(19) United States
(12) Patent Application Publication
(10) Pub. No.: US 2017/0263836 A1
(43) Pub. Date: Sep. 14, 2017

(54) PRODUCTION OF A DEVICE HAVING A STRIP-TYPE LEADFRAME

(71) Applicant: OSRAM Opto Semiconductors GmbH, Regensburg (DE)

(72) Inventors: Eu Liong Ong, Air Itam (MY); Bin Abdul Manaf Shahrol Izzanni, Georgetown (MY); Boon Liang Yap, Penang (MY); Mohd Fauzi Zainordin, Balik Pulau (MY)

(21) Appl. No.: 15/500,182

(22) PCT Filed: Jul. 29, 2015
(86) PCT No.: PCT/EP2015/067376

§ 371 Date: Jan. 30, 2017

(30) Foreign Application Priority Data
Jul. 30, 2014 (DE) 10 2014 110 781.0

(51) Int. Cl. H01L 33/62; H01L 25/00; H01L 25/075; H01L 33/48; H01L 33/54

(52) U.S. Cl. CPC H01L 33/62; H01L 33/486; H01L 33/54; H01L 25/0753; H01L 25/50; H01L 2933/0066; H01L 2933/005; H01L 2933/0033

(57) ABSTRACT

A method of producing a device includes providing a strip-shaped leadframe, wherein the leadframe includes leadframe sections arranged in a row next to one another and connection structures connecting the leadframe sections, the connection structures each connecting two adjacent leadframe sections; forming molded bodies on the leadframe, the molded bodies each mechanically connecting two adjacent leadframe sections; arranging semiconductor chips on the leadframe; and interrupting the connections of the leadframe sections realized by the connection structures.

### TECHNICAL FIELD

This disclosure relates to a method of producing a device, and to a device.

### BACKGROUND

Optoelectronic devices for lighting applications are known in various configurations. A linear lighting device generally comprises light emitting diodes (LEDs) of low or medium power which are arranged on a strip-type carrier. Such devices are therefore also referred to as LED strips or LED tape. The carrier may be a flexible circuit board or a metal core board (MCB).

Conventional production of such a lighting device involves manufacturing packaged light emitting diodes, also referred to as an LED package. This usually comprises encapsulating a metallic leadframe with a housing body comprising recesses, fixing radiation-emitting light emitting diode chips in the recesses on the leadframe, producing electrical connections by wire bonding, filling the recesses with a potting compound, and singulating the composite assembly formed thereby into the light emitting diodes. The light emitting diodes are subsequently arranged on a carrier by carrying out surface mounting (SMT, Surface Mounting Technology). The two-stage procedure of manufacturing packaged light emitting diodes separately and then arranging them on a carrier is both time-consuming and costly.

It could therefore be helpful to provide an improved method of producing a device, in particular an optoelectronic device that emits light radiation, and also a corresponding device.

### SUMMARY

We provide a method of producing a device including providing a strip-shaped leadframe, wherein the leadframe includes leadframe sections arranged in a row next to one another and connection structures connecting the leadframe sections, the connection structures each connecting two adjacent leadframe sections; forming molded bodies on the leadframe, the molded bodies each mechanically connecting two adjacent leadframe sections; arranging semiconductor chips on the leadframe; and interrupting the connections of the leadframe sections realized by the connection structures.

We also provide a device produced by carrying out the method of producing a device including providing a strip-shaped leadframe, wherein the leadframe includes leadframe sections arranged in a row next to one another and connection structures connecting the leadframe sections, the connection structures each connecting two adjacent leadframe sections; forming molded bodies on the leadframe, the molded bodies each mechanically connecting two adjacent leadframe sections; arranging semiconductor chips on the leadframe; and interrupting the connections of the leadframe sections realized by the connection structures, including a strip-shaped leadframe including leadframe sections arranged in a row next to one another; molded bodies arranged on the leadframe, the molded bodies each mechanically connecting two adjacent leadframe sections; and semiconductor chips arranged on the leadframe.

We further provide a method of producing a device including proving a strip-shaped leadframe, wherein the leadframe includes leadframe sections arranged in a row next to one another in a longitudinal direction of the leadframe and connection structures connecting the leadframe sections, the connection structures each connecting two adjacent leadframe sections of the row of leadframe sections, and the connection structures being arranged between adjacent leadframe sections of the row of leadframe sections and at opposite longitudinal sides of the leadframe; forming molded bodies on the leadframe, the molded bodies each mechanically connecting two adjacent leadframe sections of the row of leadframe sections; arranging semiconductor chips on the leadframe; and interrupting the connections of the leadframe sections realized by the connection structures.

### BRIEF DESCRIPTION OF THE DRAWING

FIG. 1 shows a plan view illustration of a strip-shaped leadframe for a linear lighting device, the strip-shaped leadframe including leadframe sections arranged in a row next to one another and connection structures in the region of opposite longitudinal sides of the leadframe, by which adjacent leadframe sections are connected.

FIG. 2 shows a plan view illustration of the linear lighting device in which the connection structures of the leadframe are removed and the leadframe sections are mechanically connected by molded bodies.

FIG. 3 shows a plan view illustration of an excerpt from the leadframe.

FIG. 4 shows a further plan view illustration of an excerpt from the leadframe.

FIG. 5 shows a greatly simplified plan view illustration corresponding to FIG. 4 and in which the connection of the leadframe sections by the connection structures is clarified.

FIG. 6 shows a plan view illustration of the leadframe in the region of the ends of the leadframe.

FIG. 7 shows a plan view illustration of an excerpt from the leadframe, wherein molded bodies including recesses are formed in mounting regions on the leadframe that mechanically connect adjacent leadframe sections.

FIGS. 8 and 9 show enlarged plan view illustrations of the leadframe in a mounting region before and after the process of forming a molded body.

FIGS. 10 and 11 show different sectional illustrations of the leadframe with a molded body.

FIG. 12 shows a plan view illustration of an excerpt from the leadframe wherein semiconductor chips are arranged on the leadframe in the recesses of the molded bodies and bond wire connections are produced.

FIG. 13 shows an enlarged plan view illustration of the leadframe in a mounting region for clarifying semiconductor chips received in a recess of a molded body.

FIG. 14 shows a plan view illustration of an excerpt from the leadframe wherein recesses of the molded bodies are filled with a potting compound.

FIGS. 15 and 16 show different sectional illustrations of the leadframe with a molded body, the recess of which is filled with the potting compound.

FIG. 17 shows a plan view illustration of an excerpt from the lighting device, wherein the connection structures of the leadframe are removed and the leadframe sections mechanically connect by the molded bodies.

FIG. 18 shows a greatly simplified plan view illustration corresponding to FIG. 17 and in which the mechanical connection of the leadframe sections by the molded bodies is clarified.

FIG. 19 shows a plan view illustration of an excerpt from the light device in which an electric current flow that occurs during the operation of the lighting device is indicated schematically.

FIG. 20 shows a greatly simplified plan view illustration corresponding to FIG. 19.

FIG. 21 shows a plan view illustration of an excerpt from the lighting device in which possible separating lines for severing the lighting device are indicated.

### LIST OF REFERENCE SIGNS

100 Lighting device
110 Leadframe
111,112 Longitudinal side
115 Connection region
120 Leadframe section
123 Hole
126 Cutout
127 Side edge
131 Cutout
132 Cutout
140 Mounting region
141, 142 Test connection region
143 Connection region
150 Connection web
160 Molded body
161 Cavity
162 Sidewall
163 Partial section
170 Semiconductor chip
172 Protective diode
175 Bond wire
180 Potting compound
200 Longitudinal direction
210 Separating line

### DETAILED DESCRIPTION

Our method comprises providing a strip-type leadframe. The leadframe comprises leadframe sections arranged in a row next to one another and connection structures connecting the leadframe sections, the connection structures each connecting two adjacent leadframe sections. The method furthermore comprises forming molded bodies on the leadframe, the molded bodies each mechanically connecting two adjacent leadframe sections. Provision is further made for arranging semiconductor chips on the leadframe, and interrupting the connections of the leadframe sections realized by the connection structures.

Instead of arranging packaged components or packages on a carrier, the method involves arranging semiconductor chips, that is to say unpackaged components, on the strip-type leadframe. As a result, it is possible to produce the device in a cost-effective manner and with a low outlay. Surface or SMT mounting may be obviated. The strip-type leadframe may serve as a carrier of the device.

In the leadframe provided, all leadframe sections positioned next to one another in a direction of extent or longitudinal direction of the leadframe mechanically connect to one another only by the connection structures. Each connection structure connects two adjacent leadframe sections. The mechanical connection enables a simple and reliable handling of the leadframe in the production method. On account of the connection structures, the leadframe is prevented from falling apart.

By the connection structures, the leadframe sections are not only mechanically but also electrically directly connected to one another and thereby short-circuited. The method therefore provides for separating the connections of the leadframe sections realized by the connection structures. The electrical short-circuit connections of the leadframe sections are thereby interrupted. As a result, it is possible to electrically operate the device manufactured in accordance with the method or to feed to the device electrical energy to operate the semiconductor chips.

Further possible details and examples of the method and of the device manufactured with the aid of the method are described in greater detail below.

The device produced with the aid of the method may furthermore comprise the leadframe sections arranged in a row next to one another and thus comprise, like the leadframe, a strip-type geometry. Furthermore, the device may be an optoelectronic device that emits light radiation. In this example, radiation-emitting semiconductor chips are arranged on the leadframe. The radiation-emitting semiconductor chips may be light emitting diode (LED) chips. In this way, the device manufactured with the aid of the method may be a linear lighting device or an LED strip.

The leadframe used in the method is formed in an electrically conductive or metallic fashion. Providing the leadframe may comprise providing a metallic starting layer and structuring the metallic starting layer into the leadframe comprising the leadframe sections and the connection structures. The structuring may be performed by etching. Mechanical structuring is also possible, for example, by stamping and/or embossing. After the structuring, coating the leadframe with a metallic coating may furthermore be carried out, for example, by electroplating. On account of the coating, the leadframe may be suitable for soldering and connecting bond wires. Forming the coating may be taken into consideration, for example, if a metallic starting layer composed of copper is used.

In a further example of the method, interrupting the connections of the leadframe sections realized by the connection structures comprises removing the connection structures. In this way, the short-circuit connections of the leadframe sections may be separated with high reliability. Removing the connection structures may be performed mechanically, for example, by stamping.

Interrupting the connections of the leadframe sections realized by the connection structures may be carried out after forming a further mechanical connection of the leadframe sections, that is to say a mechanical connection of all the leadframe sections in addition to the connection structures. As soon as such a state is present, the connections of the leadframe sections by the connection structures are dispensable. For this purpose, use may be made of the molded bodies arranged on the leadframe or in each case on two adjacent leadframe sections, by which molded bodies respectively adjacent leadframe sections and thus all leadframe sections are mechanically connected.

In this sense, in accordance with a further examples, it is provided that interrupting the connections of the leadframe sections realized by the connection structures is carried out after forming the molded bodies. In this case, the molded bodies may be used as mechanical connection elements to mechanically stabilize the leadframe and hold the leadframe sections together.

Forming the molded bodies on the leadframe may be carried out, for example, with the aid of a molding process. By way of example, transfer molding, injection molding or compression molding is possible. An electrically insulating molding compound may be used in this case.

With regard to the molded bodies, it is furthermore possible for the leadframe to be formed with structures to enable an anchoring or meshing of the molded bodies. A configuration of the leadframe with cutouts and step-type side edges of leadframe sections is possible, for example. A reliable fixing of the molded bodies on the leadframe and thus reliable mechanical connections of the leadframe sections may be achieved in this way.

The molded bodies formed in the method may serve as housing bodies for the semiconductor chips. In this sense, in accordance with a further example, it is provided that the molded bodies are formed with recesses or cavities to receive the semiconductor chips. The semiconductor chips may be protected against external influences in this way. In the region of the recesses, the leadframe may be exposed on the front side.

Each molded body may be formed with a single recess. Furthermore, the semiconductor chips may be arranged in the recesses of the molded bodies on the leadframe after the process of forming the molded bodies.

The molded bodies may be formed in mounting regions on the leadframe in which mounting regions the semiconductor chips may also be positioned on the leadframe. The mounting regions may be provided at a distance from one another in the region of the center of the strip-type leadframe and along a direction of extent or longitudinal direction of the leadframe.

With the use of radiation-emitting semiconductor chips, the recesses or the sidewalls of the recesses of the molded bodies may serve as reflectors. In this case, the sidewalls may be formed to run obliquely with respect to the leadframe in cross section.

In a further example of the method, the recesses of the molded bodies are filled with a potting compound. As a result, the semiconductor chips received in the recesses may be encapsulated, and thereby reliably protected against external influences.

With the use of radiation-emitting semiconductor chips, a phosphor-filled potting compound may be used. A conversion of a (primary) radiation generated by the semiconductor chips may be brought about.

Each molded body brings about a mechanical connection between two adjacent leadframe sections. In the leadframe provided, a separating region or a cutout, for example, a cutout running in a step-type manner as indicated further below, may be present in each case between adjacent leadframe sections. Consideration may be given here to forming the molded bodies such that the molded bodies are also arranged in such cutouts between adjacent leadframe sections and close the cutouts at these locations. The recesses of the molded bodies may thus be closed at the bottom as a result of which the potting compound may be prevented from escaping at the rear side when the potting compound is introduced into the recesses of the molded bodies.

In the context of arranging the semiconductor chips on the leadframe or after arranging the semiconductor chips on the leadframe, the electrical connections between the leadframe and semiconductor chips may furthermore be produced. This may be carried out before or after interrupting the connections of the leadframe sections realized by the connection structures. Processes such as, for example, wire bonding and/or soldering may be used. It is also possible for semiconductor chips to electrically connect directly among one another. The following configurations may furthermore be taken into consideration in this context.

The semiconductor chips may comprise two front-side contacts, for example. In this way, it is possible to produce electrical connections between semiconductor chips and the leadframe, and also of semiconductor chips among one another with the aid of bond wires.

In a further example, electrical connections between the leadframe and semiconductor chips are produced such that in a state in which the connections of the leadframe sections by the connection structures are interrupted, the semiconductor chips or groups of semiconductor chips electrically connect in series. In this example, after interrupting the short-circuit connections, the leadframe sections form a part of the electrical series connection.

The semiconductor chips may be arranged on the leadframe, for example, such that each semiconductor chip is provided on a dedicated leadframe section or a respective semiconductor chip is provided per mounting region. A semiconductor chip may each electrically connect to two leadframe sections, i.e., to the leadframe section on which the semiconductor chip is located, and to an adjacent leadframe section. In this sense, the two leadframe sections may serve as cathode and anode of the relevant semiconductor chip. In this case, it may furthermore be provided that each of the semiconductor chips is received in a dedicated recess of a corresponding molded body.

It is also possible to arrange the semiconductor chips on the leadframe such that a group of a plurality of semiconductor chips, for example, two semiconductor chips, is in each case provided on a dedicated leadframe section or a group of a plurality of semiconductor chips is in each case provided per mounting region. The semiconductor chips of a group may each be electrically connected, for example, in series among one another. Furthermore, a group may each electrically connect to two leadframe sections, i.e., to the leadframe section on which the group is located, and to an adjacent leadframe section. The two leadframe sections may thus serve as cathode and anode of the relevant group. In this case, it may furthermore be provided that each of the semiconductor chip groups is received in a recess of a corresponding molded body.

With regard to the abovementioned or other configurations, the leadframe sections of the strip-type leadframe may serve as cathode and anode or cathode area and anode area for semiconductor chips or groups of semiconductor chips. Provided that the connection structures of the leadframe are intact and not interrupted, all cathode and anode areas are electrically short-circuited. Such short-circuit connections are eliminated by interruption of the connections of the leadframe sections realized by the connection structures.

It is possible to arrange further electrical and/or electronic components, for example, protective diodes on the leadframe. Such components may each be assigned to a semiconductor chip or to a semiconductor chip group. Moreover, such components may, for example, interconnect electrically in parallel with the relevant semiconductor chips or semiconductor chip groups and received in the recesses of the associated molded bodies.

In a further example of the method, the connection structures of the leadframe provided are arranged between adjacent leadframe sections and at opposite longitudinal sides of the leadframe. Simple interruption of the connections of the leadframe sections realized by the connection structures is possible in this way.

The connection structures may be realized in web-type fashion or in the form of connection webs.

A plurality of connection structures may each be arranged at the longitudinal sides of the leadframe between adjacent leadframe sections. In this case, the connection structures may be realized such that they are relatively small or with a small width. Simple interruption of the connections of the leadframe sections realized by the connection structures may be fostered. The use of each of a plurality of connection structures at the edge of the leadframe between adjacent leadframe sections enables a high mechanical stability of the leadframe.

In a further example, the connection structures arranged at the opposite longitudinal sides are located at corresponding positions or positions with a corresponding level with respect to a longitudinal direction of the leadframe. Simple severing of the connections of the leadframe sections realized by the connection structures may be fostered further as a result.

In a further example, in the leadframe provided, a cutout running in a step-type manner in plan view is present between adjacent leadframe sections. In this way, leadframe sections of the leadframe arranged next to one another may comprise a step-type shape extending substantially diagonally with respect to the longitudinal direction of the leadframe. This may apply to all of the leadframe sections apart from leadframe sections at the ends of the strip-type leadframe. The leadframe sections at the end sides may be substantially triangular.

The leadframe provided may furthermore be formed such that the connection structures arranged at opposite longitudinal sides of the leadframe are adjacent in the region of the ends of the step-type cutouts.

Furthermore, the abovementioned mounting regions for the molded bodies and semiconductor chips may be provided in the region of the step-type cutouts and thus at the transition between adjacent leadframe sections separated by the step-type cutouts. At these locations, the step-type cutouts may run along a longitudinal direction of the leadframe.

In a further example, in the leadframe provided, a leadframe section arranged between two leadframe sections at a longitudinal side of the leadframe connects to one of the two leadframe sections by at least one connection structure and to the other of the two leadframe sections by at least one connection structure at an opposite longitudinal side with respect thereto and at a corresponding position with respect to a longitudinal direction of the leadframe. This structure may apply to all of the leadframe sections apart from leadframe sections at the ends of the strip-type leadframe.

It is possible for the length of the strip-type device manufactured with the aid of the method subsequently to be shortened in a flexible manner or for the device to be divided into a plurality of shorter devices in a flexible manner. For this purpose, the device or the leadframe is severed at one or more locations such that shorter parts of the device are present that may comprise a smaller number of semiconductor chips (or else only one semiconductor chip). This procedure may be taken into consideration, for example, with regard to a configuration of the device in the form of a linear lighting device comprising radiation-emitting semiconductor chips. In a shortened device, the semiconductor chips or groups of semiconductor chips, as the previously undivided device, may be electrically connected in series.

The flexible division may be fostered by abovementioned examples such as the connection structures arranged at opposite longitudinal sides and at corresponding positions with respect to the longitudinal direction, the step-type cutouts or the step-type shape of the leadframe sections or the like. In this case, the device may be severed along one or more separating lines. The separating lines may run perpendicular to a longitudinal direction of the leadframe or of the lighting device. Moreover, the separating lines may be provided in regions in which leadframe sections of the leadframe were previously connected by connection structures. Therefore, separation is no longer required in these regions. During severing, a leadframe section may be severed or halved along a separating line.

Moreover, further details and configurations may be taken into consideration for the production method. It is possible, for example, to provide the leadframe with cutouts arranged in a linear fashion or are formed in the form of broken lines. By way of example, functional regions of the leadframe sections may be defined and identified.

One possible example of functional regions that may be identified with such cutouts is the above-mentioned mounting regions for molded bodies and semiconductor chips. In a mounting region, one or more semiconductor chips may be arranged on the leadframe. In this context, it is furthermore possible to use cutouts that identify mounting regions to anchor the molded bodies, and introduce the molded bodies or material of the molded bodies into such cutouts.

Further examples of possible functional regions that may be highlighted with the aid of cutouts are regions provided to contact the leadframe for test purposes and regions to arrange a connection element. Such a connection element may be formed, for example, to connect a leadframe section to an electrical line or a cable.

Furthermore, consideration may be given to forming further molded bodies on the leadframe in addition to molded bodies comprising recesses to receive semiconductor chips. Such molded bodies that may serve as additional mechanical connection elements may be formed without recesses and arranged outside mounting regions for semiconductor chips on adjacent leadframe sections.

It is furthermore possible to provide the leadframe with an insulating or dielectric layer on the front side. This may be carried out after providing the leadframe and before further steps, for example, forming the molded bodies. Functional regions of the leadframe sections such as the regions described above may be left free in this case. Regions in which the connection structures of the leadframe are located may likewise be kept free. A further mechanical connection of all leadframe sections, that is to say a mechanical connection in addition to the connection structures of the leadframe, may also be made available by the insulating layer. In this configuration, therefore, consideration may be given to carrying out the process of interrupting the connections of the leadframe sections by the connection structures after the process of forming the insulating layer.

Furthermore, it is possible to arrange other semiconductor chips on the leadframe instead of radiation-emitting semiconductor chips. These include, for example, radiation-receiving semiconductor chips or else power semiconductors.

Our device is produced in accordance with the method described above or in accordance with one or more of the examples of the method described above. The device comprises a strip-type leadframe comprising leadframe sections arranged in a row next to one another. The device furthermore comprises molded bodies arranged on the leadframe, the molded bodies each mechanically connecting two adjacent leadframe sections. The device furthermore comprises semiconductor chips arranged on the leadframe.

The molded bodies may provide for mechanically holding all the leadframe sections together. A connection of the leadframe sections by material of the leadframe, on account of the severing of the short-circuit connections, is not present (any longer) in this case. Moreover, further configurations, features and details from among those mentioned above with regard to the method may be correspondingly applied to the device.

By way of example, the device may be a linear lighting device comprising radiation-emitting semiconductor chips or light emitting diode chips. Furthermore, the molded bodies may comprise recesses in which the semiconductor chips are arranged. The recesses may be filled with a potting material. The semiconductor chips or groups of semiconductor chips may electrically connect in series, wherein the leadframe sections form a part of the series connection. Cutouts running in a step-type manner may be present between the leadframe sections.

The advantageous examples and developments as explained above may be applied (apart, for example, in clear dependencies or incompatible alternatives) individually or else in arbitrary combination with one another.

The above-described properties, features and advantages and the way in which they are achieved will become clearer and more clearly understood in association with the following description of examples explained in greater detail in association with the schematic drawings.

Possible configurations of a method of producing a linear lighting device 100 present in the form of an individual string are described on the basis of the following schematic figures. The lighting device 100 formed to generate light radiation comprises a construction such that a flexible shortening of the device 100 or a flexible division of the device 100 into a plurality of shorter segments is possible.

The production of the device 100 involves providing a strip-type leadframe 110 on which radiation-emitting semiconductor chips 170 are arranged and associated housings or packages are formed. The leadframe 110 thus itself serves as a carrier of the lighting device 100. This approach makes it possible to carry out the manufacture of the lighting device 100 with a low outlay and with low costs.

The figures are merely of schematic nature and are not true to scale. In this sense, component parts and structures shown in the figures may be illustrated with exaggerated size or size reduction to afford a better understanding. In the same way, it is possible that the device 100 may comprise further component parts and structures or may be produced with further component parts and structures in addition to component parts and structures shown and described.

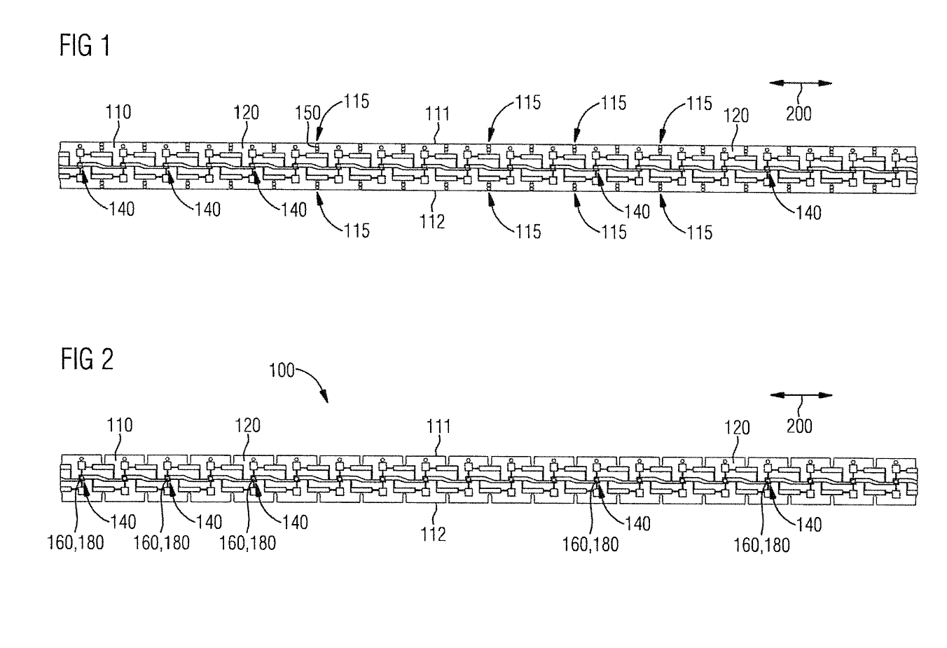

FIG. 1 shows a plan view illustration of a metallic leadframe 110 provided to produce a linear lighting device 100. The leadframe 110 is strip-type and comprises a multiplicity of leadframe sections 120 arranged in a row next to one another and connection structures 150 connecting the leadframe sections 120. A longitudinal direction 200 of the leadframe 110, along which the leadframe sections 120 are arranged next to one another, is indicated with the aid of a double-headed arrow in FIG. 1.

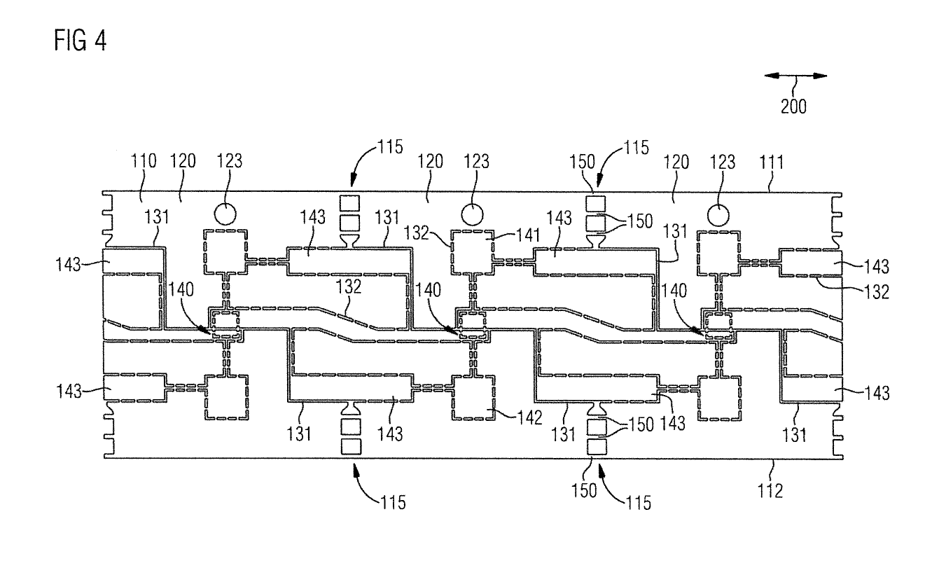

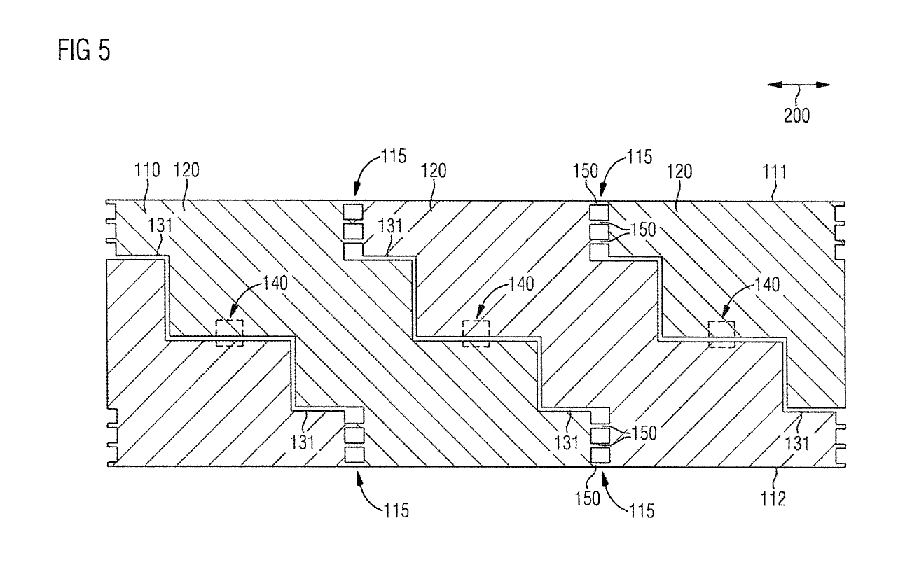

The connection structures 150 of the leadframe 110 each connect two adjacent leadframe sections 120 such that all leadframe sections 120 connect to one another. The connection structures 150 are located in connection regions 115 provided at the edge of the leadframe 110 or in the region of opposite longitudinal sides 111, 112 of the leadframe 110 extending in the longitudinal direction 200. In each connection region 115, the leadframe 110 comprises three connection structures 150, as is also shown in the excerpt illustrations in FIGS. 3 and 4. The connection structures 150 each located between two adjacent leadframe sections 120 and connecting the latter are formed in a web-type fashion and comprise a small width. The connection structures 150 are designated as connection webs 150 hereinafter. The connection regions 115 present at the opposite longitudinal sides 111, 112 and also the associated connection webs 150 are located with respect to the longitudinal direction 200 of the leadframe 110, in each case at corresponding positions or positions at a corresponding level (cf. FIGS. 1 and 4).

Providing the metallic leadframe 110 comprising the leadframe sections 120 and the connection webs 150 may comprise providing a metallic starting layer, for example, composed of copper and structuring the layer into the leadframe 110. Structuring the starting layer may be performed by etching, for example. After the structuring, coating the leadframe 110 with a metallic coating may furthermore be carried out.

In the leadframe 110 provided, the leadframe sections 120 mechanically connect in the region of the longitudinal sides 111, 112 by the connection webs 150 arranged between the leadframe sections 120. The connection webs 150 provide for a sufficient mechanical stability of the leadframe 110 such that simple and reliable handling of the leadframe 110 during the production of the lighting device 100 is possible. On account of the mechanical connection, the leadframe 110 is prevented from falling apart.

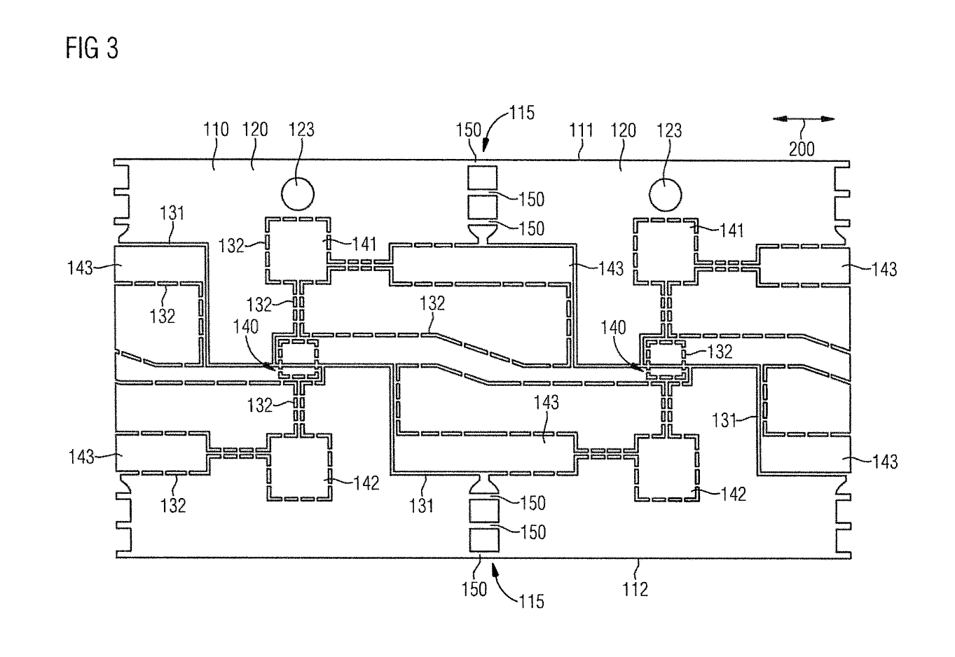

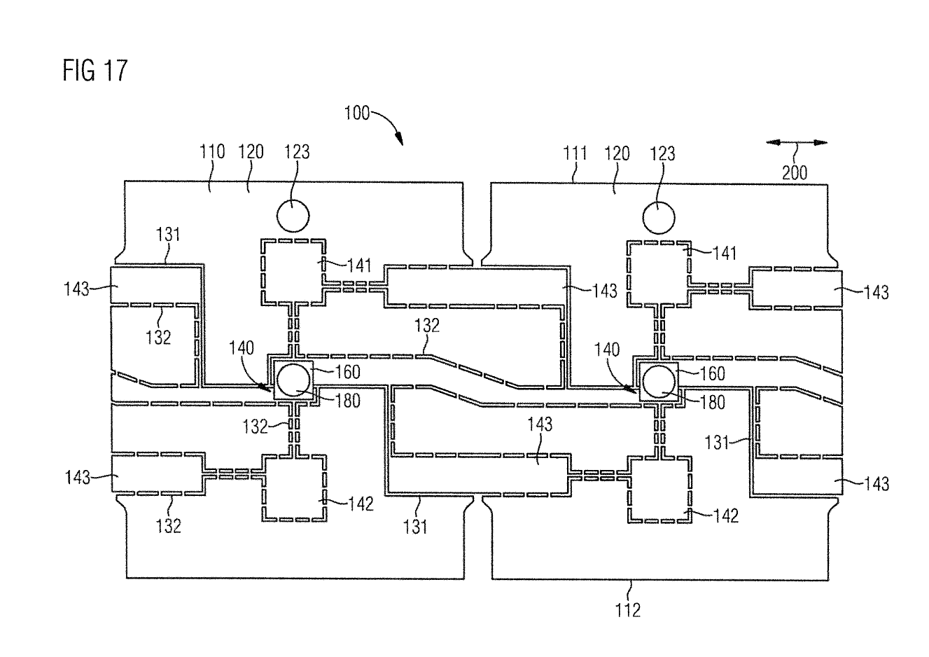

By the connection webs 150, the leadframe sections 120 serving as cathodes and anodes for semiconductor chips 170 in the lighting device 100 are not only mechanically but also electrically directly connected to one another and thereby short-circuited. In the course of the method, therefore, provision is made for separating the connections of the leadframe sections 120 realized by the connection webs 150, and thus for separating the short-circuit connections. For this purpose, the connection webs 150 are removed, as is shown in the excerpt illustration in FIG. 17 and in the plan view illustration of the lighting device manufactured in accordance with the method in FIG. 2. After the short-circuit connections have been interrupted, the lighting device 100 may be electrically operated to emit light radiation.

In the context of production of the lighting device 100, further steps are carried out besides interrupting the short-circuit connections. These include forming molded bodies 160 and arranging radiation-emitting semiconductor chips 170 on the leadframe 110. Such component parts 160, 170 are arranged in mounting regions 140 on the leadframe 110, which mounting regions are provided at a distance from one another in the region of the center of the strip-type leadframe 110 and along the longitudinal direction 200 of the leadframe 110 (cf. FIGS. 1, 2 and 12).

The molded bodies 160 serve as housing bodies for the semiconductor chips 170 and each bring about a mechanical connection of two adjacent leadframe sections 120. In this way, the molded bodies 160 may be used as mechanical connection elements which, like the connection structures 150 of the leadframe 110, may provide for mechanically holding together all leadframe sections 120 of the leadframe 110. After the process of forming the molded bodies 160, the connections of the leadframe sections 120 by the connection structures 150 are dispensable and, therefore, as indicated above, may be removed to bring about electrical isolation of the cathodes and anodes.

Before such processes of the production method carried out after providing the strip-type leadframe 110 are described in detail, first, the configuration and geometrical structure of the leadframe 110 and the leadframe sections 120 thereof will be discussed in greater detail.

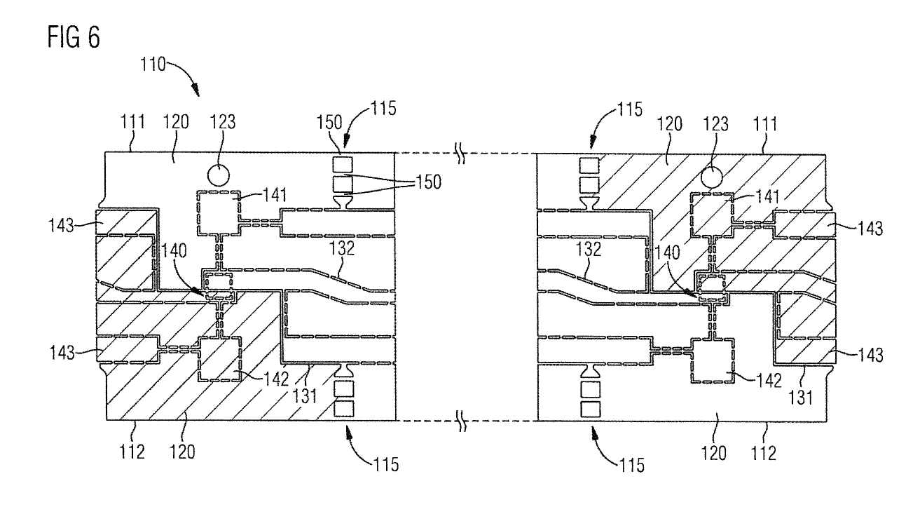

In the leadframe 110 provided, a gap-type cutout 131 running in a step-type manner is present in each case between two adjacent leadframe sections 120. In the region of the ends of the step-type cutouts 131, the connection regions 115—present at the longitudinal sides 111, 112—with the connection webs 150 are adjacent. This configuration becomes clear from a comparison of FIGS. 4 and 5.

FIG. 5 shows a greatly simplified illustration of an excerpt from the leadframe 110 corresponding to FIG. 4 and in which the cutouts 131 (with increased width) extending in a step-type manner and the connection regions 115 adjacent at the ends of the cutouts 131 are illustrated schematically. The connection of the leadframe sections 120 realized by the connection webs 150 becomes clear from this illustration. In FIG. 5, the leadframe sections 120 are highlighted with the aid of different hatchings for differentiation. In addition to the step-type cutouts 131 thereof, the leadframe 110 or the leadframe sections 120 thereof comprise further cutouts 132 arranged in a linear fashion (cf. FIG. 4), which will be discussed in greater detail further below.

FIG. 5 makes it clear that the leadframe sections 120 arranged next to one another as shown here, on account of the step-type cutouts 131 present on both sides of the leadframe sections 120, comprise a step-type shape extending substantially diagonally with respect to the longitudinal direction 200 of the leadframe 110. Furthermore, a leadframe section 120 arranged between two leadframe sections 120 in each case at the longitudinal side 111 of the leadframe 110 connects to one of the two leadframe sections 120 (each section 120 arranged on the right in accordance with FIG. 5) by a plurality of connection webs 150 and to the other of the two leadframe sections 120 (each section 120 arranged on the left in accordance with FIG. 5) by a plurality of connection webs 150 at the opposite longitudinal side 112 with respect thereto and at a corresponding position with respect to the longitudinal direction 200 of the leadframe 110. This structure and geometry are present in all of the leadframe sections 120, apart from relatively small leadframe sections 120 at the two ends of the strip-type leadframe 110 (left and right ends in the illustration in accordance with FIG. 1).

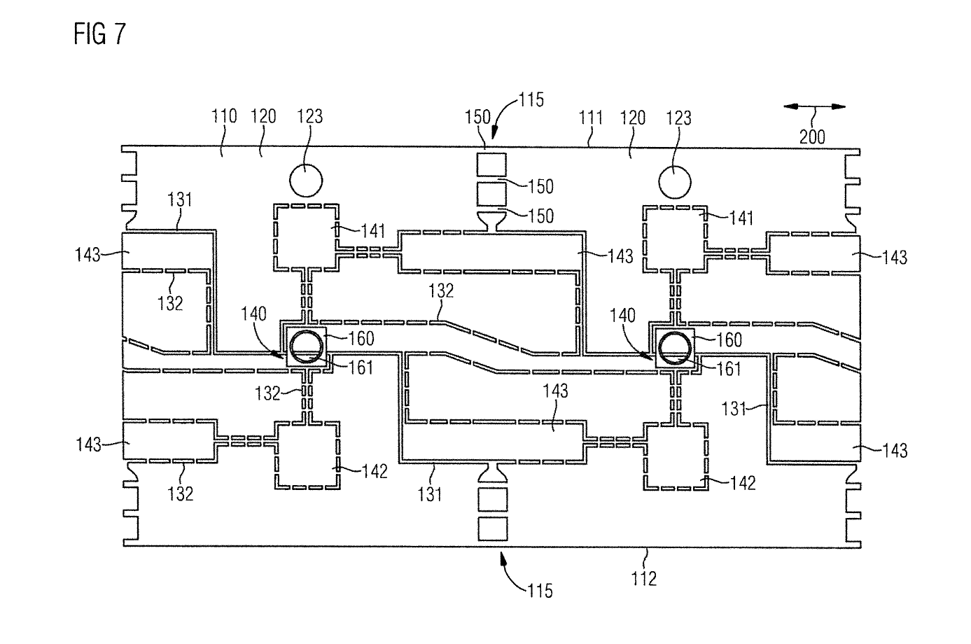

To clarify this situation, the ends of the leadframe 110 provided are illustrated as an excerpt in FIG. 6. The two end-side leadframe sections 120, which are highlighted with the aid of hatchings in FIG. 6, are substantially triangular and may be regarded as “halved” leadframe sections 120 which, when combined, may yield a diagonally extending “whole” leadframe section 120. Furthermore, the end-side leadframe sections 120 connect to an adjacent leadframe section 120 by a plurality of connection webs 150 only at one of the longitudinal sides 111, 112.

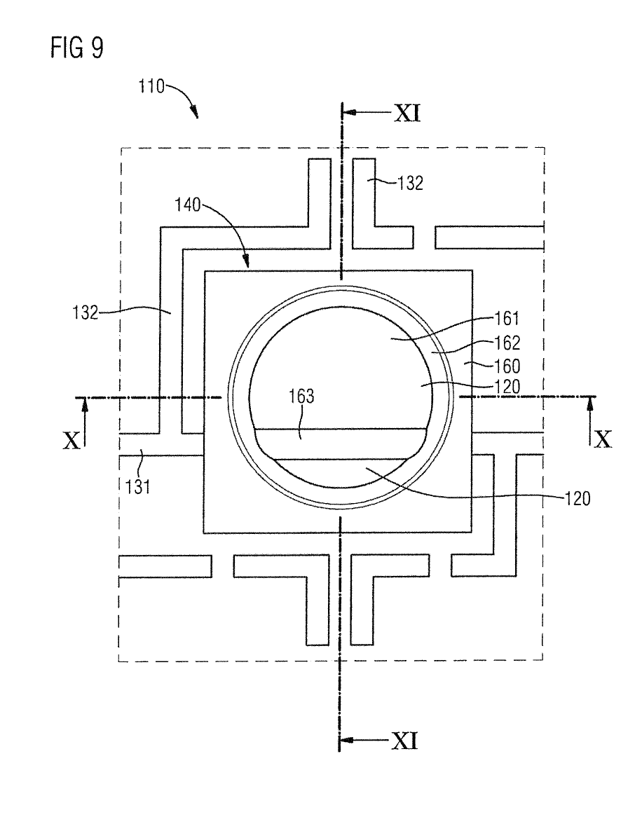

In addition to the cutouts 131 running in a step-type manner in plan view and separate adjacent leadframe sections 120, the leadframe 110 provided comprises a multiplicity of further cutouts 132 arranged in a linear fashion or are present in the form of broken lines, as is shown in FIGS. 3 and 4. These cutouts 132, which in part also connect to the step-type cutouts 131 or proceed from the cutouts 131 (cf., for example, the region 140 shown in FIG. 8) serve to identify functional regions of the leadframe 110.

These include the mounting regions 140 present in the center of the leadframe 110 in a manner spaced apart along the longitudinal direction 200. The mounting regions 140 are highlighted with the aid of cutouts 132 extending circumferentially in a rectangular or square fashion in the form of broken lines. The mounting regions 140 are each provided at two adjacent leadframe sections 120 or at the transition of two adjacent leadframe sections 120 separated by a corresponding step-type cutout 131. The step-type cutouts 131 thus also extend through the mounting regions 140 highlighted with the aid of the cutouts 132, as is indicated schematically in FIG. 5 (cf. furthermore FIG. 8). At these locations, the step-type cutouts 131 run parallel to or along the longitudinal direction 200 of the leadframe 110.

Further functional regions identified with the aid of the cutouts 132 arranged in a linear fashion are rectangular test connection regions 141, 142, at which the leadframe 110 and the manufactured device 100 may be contacted for test purposes (cf. FIGS. 3 and 4). In this case, the regions 141 may be cathode test connection regions and the regions 142 may be anode test connection regions.

The leadframe 110 is furthermore formed with circular holes 123 located near the test connection regions 141 (cf. FIGS. 3 and 4). The polarity or function as cathode of the test connection regions 141 and of the leadframe sections 120 in this region is represented by the holes 123.

With the aid of the cutouts 132 (and in part the cutouts 131), rectangular connection regions 143 are furthermore highlighted (cf. FIGS. 3 and 4). In the manufactured lighting device 100 or in a device that emerges from the device 100 by division, for example, connection elements (not illustrated) for producing a connection to an electrical line or a cable may be mounted at these locations, for example, by soldering. The connection regions 143 (cf. FIG. 6) present at the two ends may each be used for this purpose. The completed lighting device 100 or a device emerging therefrom may be supplied with electrical energy by the connection elements.

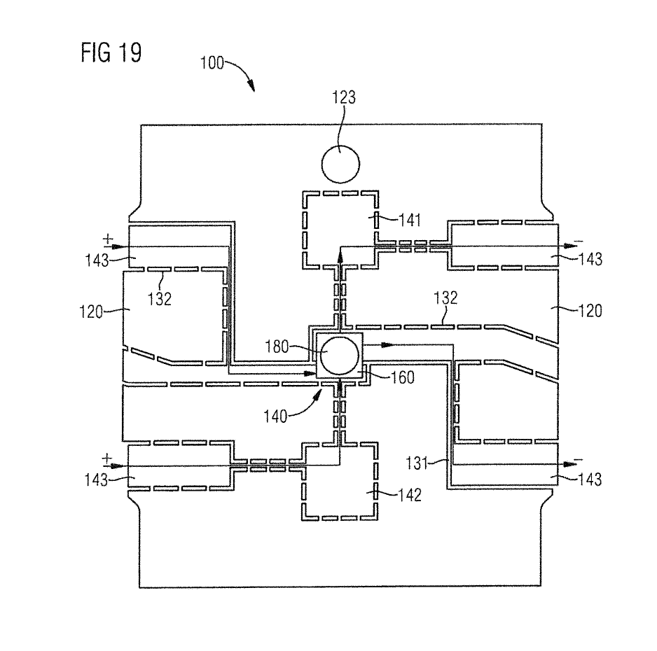

Furthermore, linear connections and thus fictitious current paths (cf. FIG. 19) between the functional regions 140, 141, 142, 143 are highlighted by the cutouts 132 (and 131). As will be explained in even greater detail further below, the leadframe 110 may optionally be provided with an insulating or dielectric layer (not illustrated) on the front side. In this case, the holes 123, the regions 140, 141, 142, 143 and the connection regions 115 may be kept free.

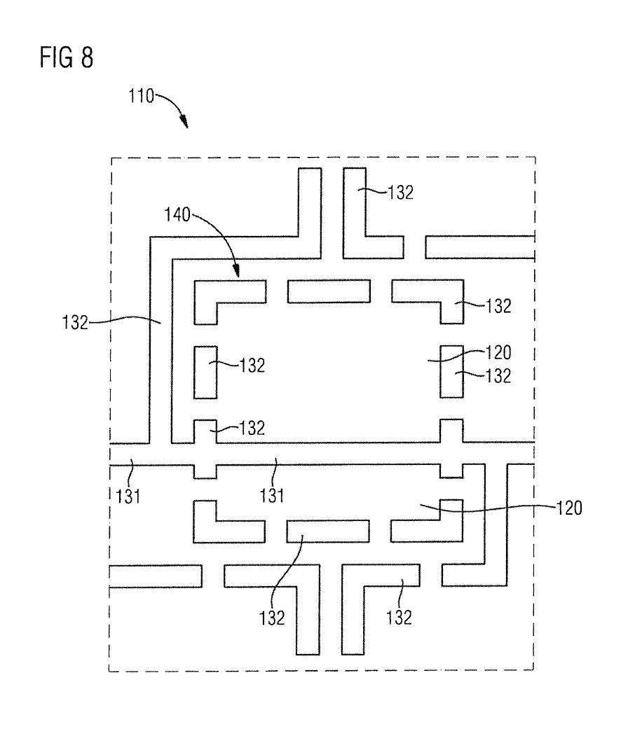

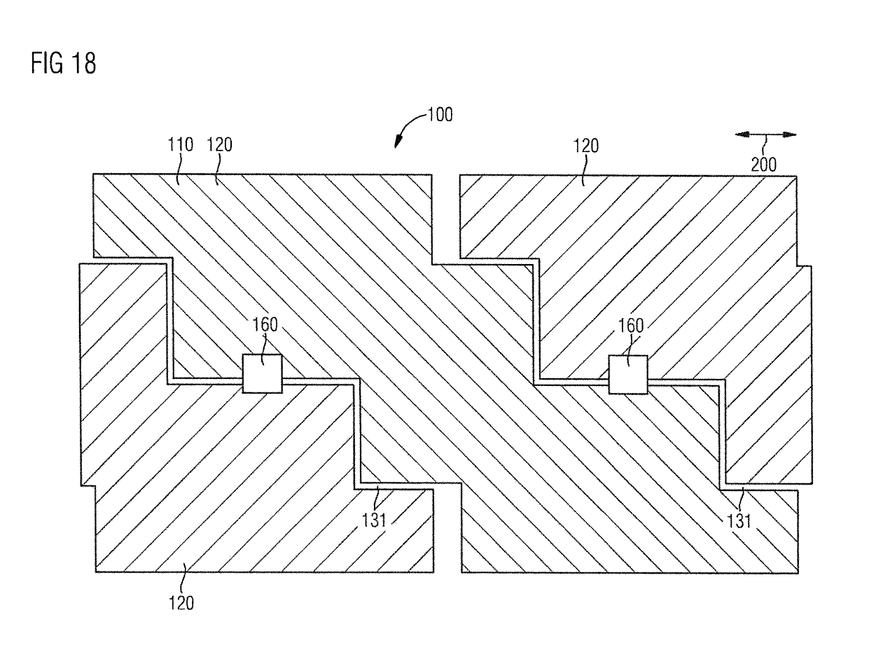

After providing the strip-type leadframe 110, the molded bodies 160 serving as housings are formed in the mounting regions 140 on the leadframe 110, as shown in the excerpt illustration in FIG. 7. The molded bodies 160 are each arranged on two adjacent leadframe sections 120, as a result of which the leadframe sections 120, and thus all leadframe sections 120 mechanically connect by the molded bodies 160, (cf. furthermore FIG. 18).

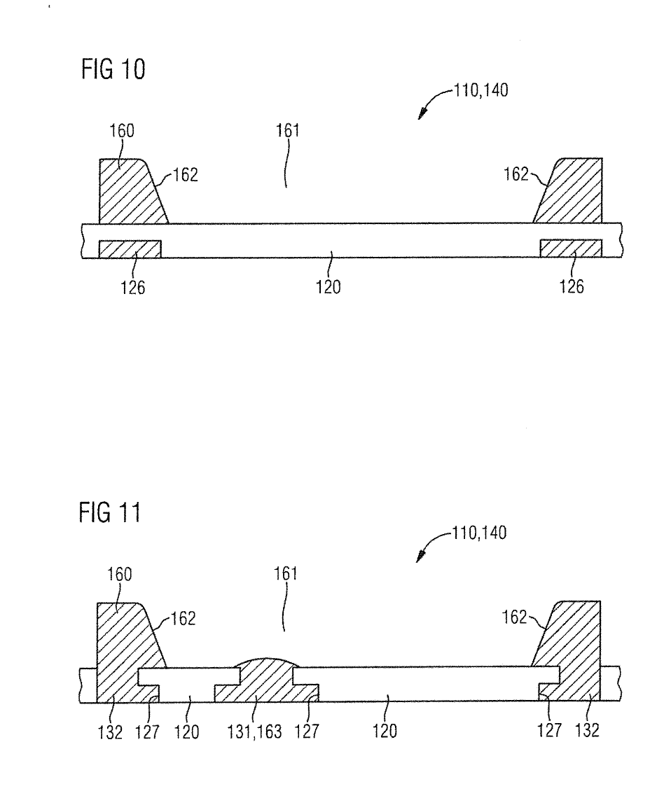

Further details with regard to the molded bodies 160 and the leadframe 110 become clear with reference to FIGS. 8 to 11. FIGS. 8 and 9 show an enlarged excerpt illustration in the region of a mounting region 140 before and after the process of forming a corresponding molded body 160. FIGS. 10 and 11 show different sectional illustrations from FIG. 9, the sectional planes relating to the sectional lines indicated in FIG. 9.

In plan view, the molded bodies 160, as shown in FIG. 9, have a rectangular or square outer contour. Furthermore, each molded body 160 comprise a circular recess or cavity 161 such that the leadframe 110 or the two leadframe sections 120 respectively associated with a molded body 160 are exposed on the front side within the cavity 161.

The cavities 161 comprise an inwardly directed sidewall 162 extending circumferentially in a circular fashion and running obliquely with respect to the leadframe 110 in cross section (cf. FIGS. 10 and 11). In this way, the molded bodies 160, may act as reflectors.

The molded bodies 160 are furthermore formed such that the cutouts 131 (which are step-type in plan view) in the mounting regions 140 are closed. For this purpose, the molded bodies 160 are formed with partial sections 163 that correspondingly fill the cutouts 131 in this region (cf. FIGS. 9 and 11). As a result, the cavities 161 of the molded bodies 160 are closed or sealed at the bottom.

The leadframe 110 and the molded bodies 160 are formed to the effect that a reliable anchoring of the molded bodies 160 on the leadframe 110 is possible. For this purpose, the molded bodies 160 or material of the molded bodies 160 are/is arranged not only in the cutouts 131, but also in the cutouts 132 that identify the mounting regions 140 and extend circumferentially in a rectangular fashion (cf. FIGS. 8, 9 and 11). At these locations, the leadframe sections 120 in the region of the cutouts 131, 132 are formed with step-type side edges 127 to anchor the molded bodies 160 as shown in FIG. 11. Furthermore, the leadframe 110 comprises rear-side cutouts or depressions 126 into which material of the molded bodies 160 is introduced for anchoring the same (cf. FIG. 10).

Forming the molded bodies 160 on the leadframe 110 is carried out with the aid of a molding process. An electrically insulating molding compound is used in this case. The molding compound may comprise a white color. Furthermore, the molding compound may be a plastics material or comprise a plastics material. The molding process may be a transfer molding process, an injection molding process or a compression molding process.

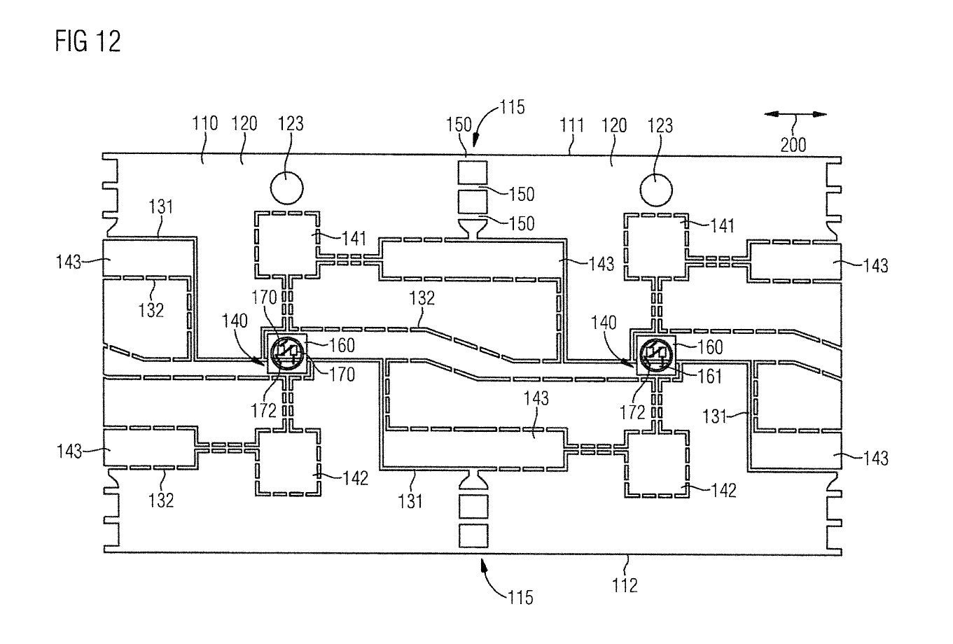

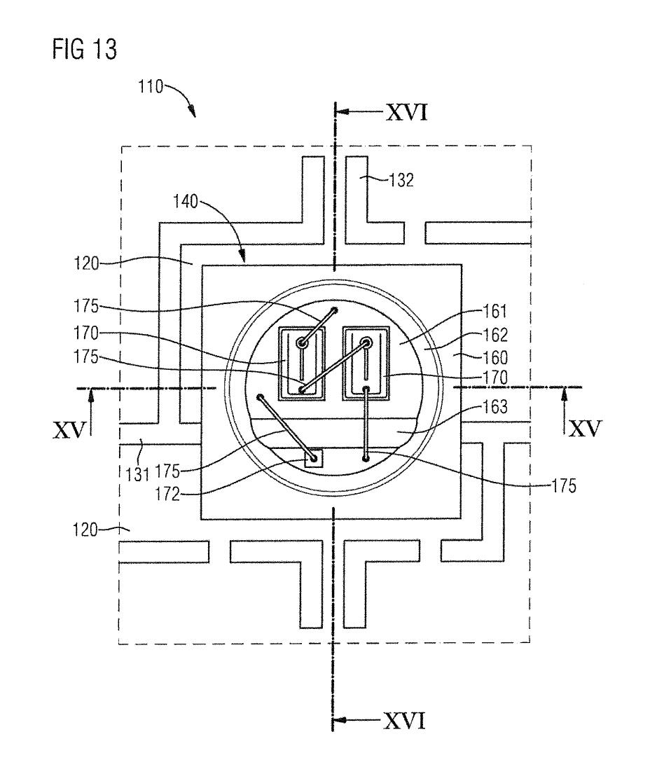

After forming the molded bodies 160, radiation-emitting semiconductor chips 170 are arranged in the cavities 161 of the molded bodies 160 on the leadframe 110 as shown in the excerpt illustrations in FIGS. 12 and 13. A group of two semiconductor chips 170 is positioned in each mounting region 140 or in each cavity 161. In the individual cavities 161, the two semiconductor chips 170 of a group each are arranged on one of the two leadframe sections 120 present or exposed at this location.

The radiation-emitting semiconductor chips 170 may be, in particular, light emitting diode chips that generate light radiation. In this way, the manufactured lighting device 100 may be an LED strip. The semiconductor or light emitting diode chips 170 may be produced in a manner known per se and comprise component parts such as a semiconductor layer sequence comprising an active zone that generates radiation. Furthermore, the semiconductor chips 170 comprise two front-side contacts, via which the semiconductor chips 170 may be supplied with electrical energy. The semiconductor chips 170 may be fixed on the leadframe 110, for example, using an adhesive or some other material such as, for example, a solder.

Furthermore, protective diodes 172 assigned to the individual semiconductor chip groups are arranged in the cavities 161 of the molded bodies 160 on the leadframe 110, as is likewise illustrated in FIGS. 12 and 13. The protective diodes 172 are positioned on leadframe sections 120 adjacent to the leadframe sections 120 carrying the semiconductor chips 170. The protective diodes 170 that serve as protection against electrostatic discharge are also designated as ESD protective diodes. The protective diodes 172 comprise a front-side contact and a rear-side contact. By the rear-side contact, the protective diodes 172 are mounted on the leadframe 110, for example, using a solder or an electrically conductive adhesive.

It is possible to perform the equipping of the leadframe 110 with the semiconductor chips 170 and the protective diodes 172 jointly, or else separately from one another.

Afterward, as is likewise illustrated in FIGS. 12 and 13, electrical connections in the form of bond wires 175 are produced. In this case, the radiation-emitting semiconductor chips 170 in the individual semiconductor chip groups are electrically connected in series among one another, and the semiconductor chip groups are electrically connected in series with the associated leadframe sections 120. By the process of removing the connection webs 150 of the leadframe 110 and thus interrupting the short-circuit connections, as provided in the production method, an electrical series connection of the semiconductor chip groups among one another or of all semiconductor chips 170 may be realized. The protective diodes 175 interconnect in parallel or in antiparallel with the associated semiconductor chip groups.

The bond wires 175 connect to the front-side contacts of the radiation-emitting semiconductor chips 170 and of the protective diodes 172 and, also, with the exception of bond wires 175 for the direct connection of semiconductor chips 170, to the leadframe 110. In each semiconductor chip group, one of the two semiconductor chips 170 connect by a bond wire 175 to the leadframe section 120 on which the group is located, and the other of the two semiconductor chips 170 connect by a bond wire 175 to the leadframe section 120 adjacent thereto. The protective diodes 172 connect by bond wires 175 to the respectively adjacent leadframe sections 120 carrying the associated semiconductor chips 170.

With regard to the semiconductor chip groups, the leadframe section 120 on which a group is located may each serve as a cathode of the group. The other or adjacent leadframe section may each serve as an anode. A leadframe section 120 may thus serve as a cathode and as an anode for different semiconductor chip groups.

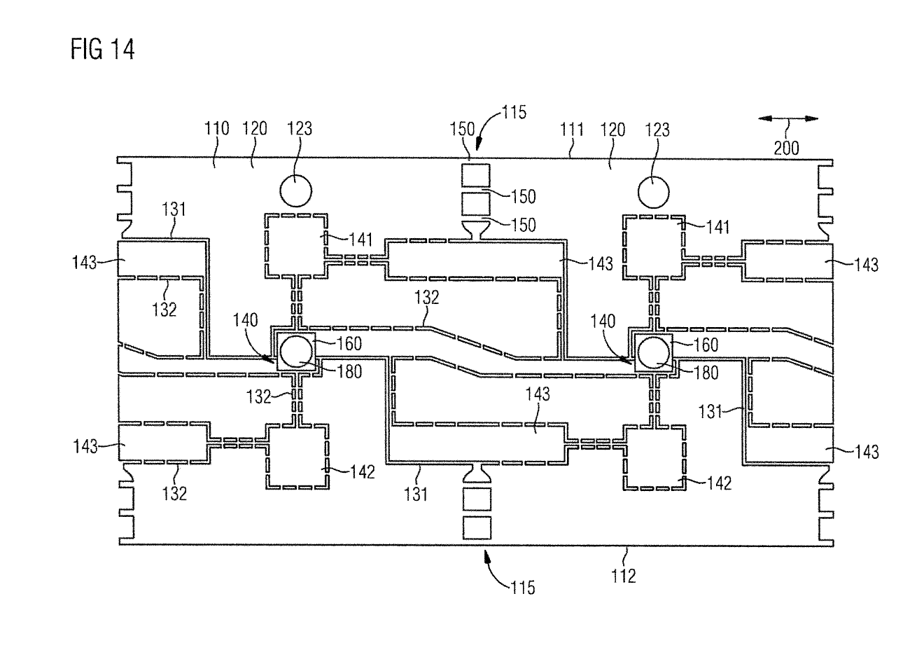

After arranging and wiring the semiconductor chips 170 and protective diodes 172, the cavities 161 of the molded bodies 160 are filled with a potting compound 180 as shown in the plan view illustration in FIG. 14. As a result, the semiconductor chips 170 and protective diodes 172 arranged and wired within the cavities 161 are encapsulated as a result of which they are reliably protected against external influences. Introducing the potting compound 180 into the cavities 161 may be carried out, for example, with the aid of a dispensing or metering method.

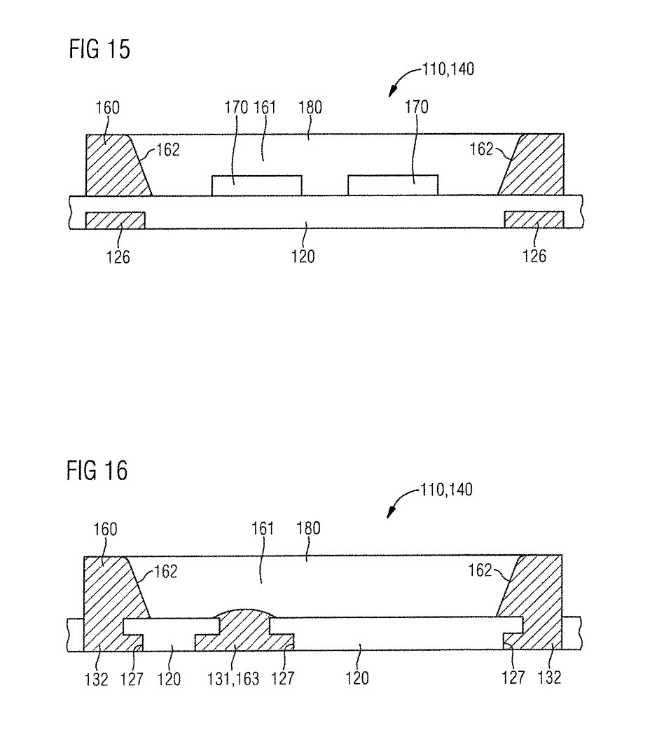

The cavities 161 may be filled with the potting compound 180 as far as the front side of the molded bodies 160, as shown in the sectional illustrations in FIGS. 15 and 16. The associated sectional planes relate to the sectional lines indicated in FIG. 13. On account of the partial sections 163 of the molded bodies 160 and the sealing of the cavities 161 at the bottom, as achieved thereby, the potting compound 180 may be prevented from escaping at the rear side during the process.

The potting compound 180 may be a phosphor-filled potting compound 180 comprising one or more conversion materials. In this case, the potting compound 180 may comprise a radiation-transmissive potting or matrix material, for example, silicone, and phosphor-particles embedded therein (not illustrated). In this way, at least part of a (primary) radiation generated by the radiation-emitting semiconductor chips 170 during operation may be converted with the aid of the potting compound 180 (volume conversion).

After filling the cavities 161, packaged light sources or LED light sources comprising two radiation-emitting semiconductor chips 170 are present in the region of the individual mounting regions 140. However, they are still short-circuited. To complete the lighting device 100 shown in FIG. 2, therefore, the connection webs 150 of the leadframe 110 that connect the leadframe sections 120 are removed. This is illustrated in the excerpt illustration in FIG. 17.

Removing the connection webs 150 may be carried out mechanically, for example, with the aid of a stamping process. This operation may be carried out as simply as possible on account of the small connection webs 150 and the arrangement thereof at the longitudinal sides 111, 112 of the leadframe 110.

Removing the connection webs 150 has the consequence that the short-circuit connections of the leadframe sections 120 serving as cathodes and anodes are interrupted as a result of which the semiconductor chips 170 or semiconductor chip groups now electrically connect in series. To put it another way, an electrical series connection of the semiconductor chips 170 or semiconductor chip groups arranged in the mounting regions 140 is provided as a result of the removal of the connection webs 150. In this case, the leadframe sections 120 arranged next to one another form a part of the electrical series connection.

After removing the connection webs 150, the molded bodies 160 provide for mechanically holding together the leadframe sections 120 of the leadframe 110 in a stable manner. This relationship is clarified supplementarily in FIG. 18, in which the lighting device 100 is illustrated as an excerpt and in a greatly simplified manner.

To operate the lighting device 100 for emitting light radiation, electrical energy may be fed to the lighting device 100 via the two leadframe sections 120 present at the ends (cf. FIG. 6). As was indicated above, connection elements arranged at the connection regions 143 of the end-side leadframe sections 120 may be used for this purpose (not illustrated). It is possible here for only each one of the connection regions 143 or both connection regions 143 of an end-side leadframe section 120 to be used or provided with a connection element.

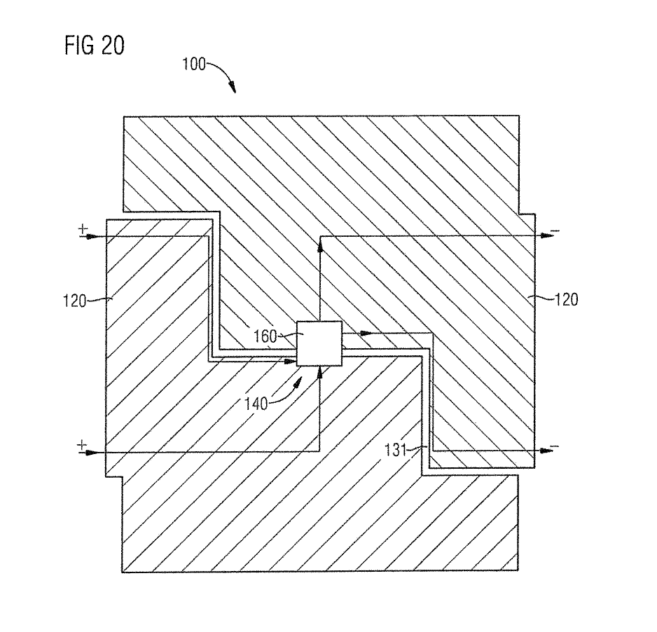

During operation of the lighting device 100, an electric current may flow through all of the series-connected semiconductor chips 170 and also the protective diodes 172. This is illustrated schematically in the plan view illustration of an excerpt from the lighting device 100 as shown in FIG. 19, and the greatly simplified illustration corresponding thereto in FIG. 20. In this case, the leadframe section 120 arranged on the left in FIGS. 19 and 20 serves as an anode (positive pole), and the leadframe section 120 arranged on the right serves as a cathode (negative pole).

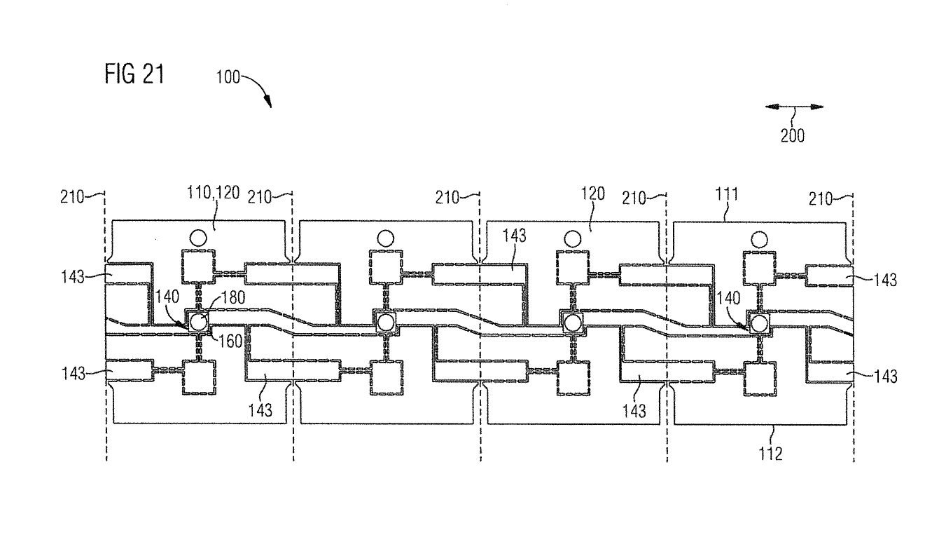

Construction of the lighting device 100 makes it possible to shorten the lighting device 100 in a flexible manner or to divide it into a plurality of shorter devices comprising a smaller number of radiation-emitting semiconductor chips 170. As indicated in FIG. 21 with the aid of an excerpt from the lighting device 100, the lighting device 100 or the leadframe 110 thereof may be severed at one or else a plurality of separating lines 210 for this purpose. The separating lines 210 run perpendicular to the longitudinal direction 200 of the leadframe 110 or of the lighting device 100 and are provided in each region in which the connection webs 150 connecting the leadframe sections 120 were previously present. In a shortened device, the semiconductor chips 170 or groups of semiconductor chips 170 may be electrically connected in series, as the previously undivided device 100.

Dividing involves severing or halving a leadframe section 120 along a separating line 210 as a result of which two end-side leadframe sections 120 comprising connection regions 143 present at the edge may emerge from such a leadframe section 120 (cf. FIG. 6). As a result, the shorter devices formed by dividing may have a corresponding appearance in the region of the opposite ends. Such dividing is made possible by the above-described configuration of the leadframe 110 comprising the connection regions 115 provided at the longitudinal sides 111, 112 and at corresponding positions with respect to the longitudinal direction 200, and by the step-type shape of the leadframe sections 120.

Dividing the lighting device 100 may be performed, for example, such that at least one shortened lighting device comprising two mounting regions 140 or two semiconductor chip groups connected in series is formed. Such a device may comprise a construction corresponding to FIGS. 17 and 18. Dividing is also possible such that at least one shortened lighting device comprising a different number of semiconductor chip groups connected in series is produced. Dividing the lighting device 100 may also be carried out such that at least one shortened lighting device comprising only one mounting region 140 or one semiconductor chip group is formed. Such a device may comprise a construction corresponding to FIGS. 19 and 20.

The examples explained with reference to the figures constitute preferred or examples of our methods and devices. Besides the examples described and shown, further examples are possible which may comprise further modifications and/or combinations of features. By way of example, it is possible to provide the strip-type leadframe 110 with other forms of leadframe sections 120, cutouts and the like.

In this context, one possible modification consists, for example, of forming connection regions 115 provided at the longitudinal sides 111, 112 with a different number of connection structures 150. By way of example, in each case only one connection structure 150 may be provided in the connection regions 115.

In a further variant, a different number of semiconductor chips 170 may be provided in the mounting regions 140 or in the cavities 161 of the molded bodies 160. It is possible, for example, to use only one semiconductor chip 170 per mounting region 140 arranged on one of the two leadframe sections 120 present at this location and connected to the two leadframe sections 120 by bond wires 175. After removing the connection structures 150, all of the semiconductor chips 170 may be connected in series. Analogously, groups comprising more than two semiconductor chips 170 may be provided for the mounting region 140, can be arranged on a leadframe section 120 in a manner comparable to FIG. 13, and electrically connect among one another by bond wires 175 and also connect to the two leadframe sections 120 present at this location. Protective diodes 172 connected in parallel may additionally be used in such examples, too.

Other radiation-emitting semiconductor chips may also be used instead of radiation-emitting semiconductor chips 170 comprising two front-side contacts. One possible example is semiconductor chips comprising one front-side contact and one rear-side contact. These may be arranged like the protective diodes 172 with the rear-side contact on a leadframe section 120, for example, using a solder or an electrically conductive adhesive. The front-side contact connects to an adjacent leadframe section 120 by a bond wire 175. Semiconductor chips comprising two rear-side contacts are also usable. These may be arranged on two adjacent leadframe sections 120 by way of the rear-side contacts, wherein a solder or an electrically conductive adhesive is usable here, too.

Furthermore, it is possible, with the use of semiconductor chip groups, to interconnect the semiconductor chips in the individual groups in parallel among one another or to provide combined series and parallel connections.

In a further modification, the radiation-emitting semiconductor chips 170 may comprise conversion layers or laminar conversion elements for radiation conversion on a front side or such conversion elements may be arranged on the semiconductor chips 170 after the semiconductor chips 170 have been arranged on the leadframe 110 (surface conversion). In this configuration, the potting compound 180 may comprise only a radiation-transmissive potting material.

With regard to removing the connection structures 150, it is possible to carry out this operation in an earlier method stage, for example, directly after forming the molded bodies 160.

A further variant consists of the connection structures 150 not being completely removed, but rather only severed such that residual partial sections of the connection structures 150 may remain. This may likewise be performed by stamping or else, for example, by sawing or cutting. Analogously, it is possible to remove not only the connection structures 150, but also larger parts of the leadframe 110 comprising the connection structures 150. The short-circuit connections of the leadframe sections 120 may be separated in this way, too.

In the context of providing the leadframe 110, a metallic starting layer may also be mechanically structured, for example, by stamping and/or embossing.

Consideration may furthermore be given to forming further molded bodies on the leadframe 110 in addition to the molded bodies 160 comprising cavities 161 for receiving semiconductor chips. Such molded bodies, which may serve as additional mechanical connection elements, may be formed without cavities 161 and be provided outside the mounting regions 140 on adjacent leadframe sections 120.

Furthermore, it is possible to provide the leadframe 110 with an additional dielectric or insulating layer at the front side. In this case, functional regions such as the mounting regions 140, the test connection regions 141, 142 and the connection regions 143, and also regions in which the connection structures 150 of the leadframe 110 are located, may remain uncovered. Such an insulating layer may be applied on the leadframe 110, for example, after providing the leadframe 110 and before forming the molded bodies 160. In this variant, an additional mechanical stabilization of the leadframe 110 or mechanical connection of the leadframe sections 120 thereof may be brought about with the aid of the insulating layer. Consideration may therefore be given to carrying out removing or severing of the connection structures 150 after forming the insulating layer.

Furthermore, it is possible to arrange other semiconductor chips on the leadframe 110 instead of radiation-emitting semiconductor chips 170. These include, for example, radiation-receiving semiconductor chips or else power semiconductors.

Although our methods and devices have been more specifically illustrated and described in detail by preferred examples, nevertheless this disclosure is not restricted by the examples disclosed and other variations may be derived therefrom by those skilled in the art, without departing from the scope of protection of the appended claims.

1-15. (canceled)

16. A method of producing a device comprising:
providing a strip-shaped leadframe, wherein the leadframe comprises leadframe sections arranged in a row next to one another and connection structures connecting the leadframe sections, said connection structures each connecting two adjacent leadframe sections;
forming molded bodies on the leadframe, said molded bodies each mechanically connecting two adjacent leadframe sections;
arranging semiconductor chips on the leadframe; and
interrupting the connections of the leadframe sections realized by the connection structures.

17. The method according to claim 16, wherein interrupting the connections of the leadframe sections by the connection structures comprises removing the connection structures.

18. The method according to claim 16, wherein interrupting the connections of the leadframe sections by the connection structures is carried out after forming the molded bodies.

19. The method according to claim 16, wherein the molded bodies are formed with recesses to receive the semiconductor chips.

20. The method according to claim 19, wherein the recesses of the molded bodies are filled with a potting compound.

21. The method according to claim 16, wherein electrical connections between the leadframe and semiconductor chips are produced such that in a state in which the connections of the leadframe sections by the connection structures are interrupted, the semiconductor chips or groups of semiconductor chips are electrically connected in series.

22. The method according to claim 16, wherein the connection structures of the leadframe provided are arranged between adjacent leadframe sections and at opposite longitudinal sides of the leadframe.

23. The method according to claim 22, wherein a plurality of connection structures are each arranged at the longitudinal sides of the leadframe between adjacent leadframe sections.

24. The method according to claim 22, wherein the connection structures arranged at the opposite longitudinal sides are located at corresponding positions with respect to a longitudinal direction of the leadframe.

25. The method according to claim 16, wherein, in the leadframe provided, a cutout running in a step manner is present between each adjacent leadframe section.

26. The method according to claim 25, wherein the leadframe sections of the leadframe provided, apart from leadframe sections at the ends of the leadframe, comprise a step shape extending substantially diagonally with respect to the longitudinal direction of the leadframe, and the leadframe sections at ends of the leadframe are substantially triangular.

27. The method according to claim 25, wherein forming the molded bodies and arranging the semiconductor chips on the leadframe are carried out in mounting regions, said mounting regions being provided in areas of the step cutouts and thus at transitions between adjacent leadframe sections, and the step cutouts run along a longitudinal direction of the leadframe in the mounting regions.

28. The method according to claim 16, wherein each molded body is formed with a single recess.

29. The method according to claim 16, wherein each connection structure of the leadframe provided connects only two adjacent leadframe sections.

30. The method according to claim 16, wherein each molded body connects only two adjacent leadframe sections.

31. The method according to claim 16, wherein the device is an optoelectronic device that emits light radiation, and the semiconductor chips are radiation-emitting semiconductor chips.

32. A device produced by carrying out the method according to claim 16 comprising:
a strip-shaped leadframe comprising leadframe sections arranged in a row next to one another;
molded bodies arranged on the leadframe, said molded bodies each mechanically connecting two adjacent leadframe sections; and
semiconductor chips arranged on the leadframe.

33. A method of producing a device comprising:
providing a strip-shaped leadframe, wherein the leadframe comprises leadframe sections arranged in a row next to one another in a longitudinal direction of the leadframe and connection structures connecting the leadframe sections, said connection structures each connecting two adjacent leadframe sections of the row of leadframe sections, and said connection structures being arranged between adjacent leadframe sections of the row of leadframe sections and at opposite longitudinal sides of the leadframe;
forming molded bodies on the leadframe, said molded bodies each mechanically connecting two adjacent leadframe sections of the row of leadframe sections;
arranging semiconductor chips on the leadframe; and
interrupting the connections of the leadframe sections realized by the connection structures.

34. The method according to claim 33, wherein, in the leadframe provided, a cutout running in a step-type manner is present between each adjacent leadframe section of the row of leadframe sections.
